(19) United States
(12) Patent Application Publication
(10) Pub. No.: US 2004/0066181 A1
(43) Pub. Date: Apr. 8, 2004

(54) High-frequency probe tip

(76) Inventor: Steffen Thies, Waging (DE)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/450,394

(22) PCT Filed: Dec. 12, 2001
(86) PCT No.: PCT/DE01/04619

(30) Foreign Application Priority Data
Dec. 21, 2000 (DE) 20021685.6

(51) Int. Cl. G01R 31/02

(52) U.S. Cl. 324/72.5

(57) ABSTRACT

The invention relates to a high frequency probe tip, particularly for printed circuit boards and/or HF cables, having a connecting end (10) to which a measuring cable may be connected for linking to a measuring device, with an earth contact (16) and a measuring tip (12), on which at least one signal contact (14) is formed, whereby a coaxial conductor (18) with an earth conductor arrangement (20) and at least one signal conductor (22) surrounded by a dielectric (24) connects the connecting end (10) to the measuring tip (12). Starting from the measuring tip (12), the earth conductor arrangement (20) is so designed over a predetermined region (30) of the high frequency probe tip that at least one of the signal conductors (22) is displaceable within the earth conductor arrangement (20) together with the dielectric (24) surrounding said signal conductor.

The invention relates to a high frequency probe tip, particularly for printed circuit boards and/or HF cables, according to the precharacterising clause of claim 1.

The problem arises when TDR (Time Domain Reflectometry) measurements are made on printed circuit boards that, for measuring purposes, different contact arrangements have to be tapped or contacted with a measuring tip. In order that a different measuring tip does not have to be used for every measurement with correspondingly adjusted separation between signal contact and earth contact, it has previously been proposed to provide a spiral pattern of recesses at the measuring tip into each of which the earth contact may be inserted. In this manner, different separations between the signal contact and the earth contact in a particular grid pattern may be realised. Changing this separation is awkward, however, since the measuring tip must be taken apart with a special tool for the purpose.

A measuring tip has also been proposed in which a measuring spike of the earth contact is rotatably arranged. Through suitable rotation of the measuring spike, different separations between the earth contact and the signal contact may be realised. However, problems arise regarding the impedance matching, and unwanted reflections limit a frequency range within which such a measuring tip may be used, to, for instance, a maximum of 125 MHz. However, nowadays, measuring tips are required that are usable into the GHz range.

The invention is based on the aim of providing an improved high frequency probe tip of the aforementioned type which is simple to handle and simultaneously ensures good functional reliability, even at high frequencies in the GHz range.

This aim is fulfilled by a high frequency probe tip of the aforementioned type having the features disclosed in claim 1. Advantageous embodiments of the invention are disclosed in the respective dependent claims.

With a high frequency probe tip of the aforementioned type, it is provided according to the invention that, starting from the measuring tip, the earth conductor arrangement is so designed over a predetermined region of the high frequency probe tip that the signal conductor is displaceable within the earth conductor arrangement together with the dielectric surrounding said signal conductor.

This has the advantage that the separation between the signal contact and the earth contact is simply and quickly adjustable in a continuous manner, whereby at the same time, an impedance matching is not impaired, so that the measuring tip according to the invention has a large bandwidth extending into the GHz range.

In that the earth conductor arrangement is designed in the predetermined region in a box-like form, the electric field between the earth conductor arrangement and the signal conductor arrangement runs in this region practically only through a correspondingly flattened region of the dielectric surrounding the signal conductor. As a result, the impedance is independent of the position of the signal conductor within the earth conductor arrangement. This effect is amplified in that the box-like earth conductor arrangement has a small and a large diameter in cross-section, whereby the small diameter is smaller than the diameter of the dielectric of the signal conductor.

For simple and functionally reliable adjustment of the separation between the signal contact and the earth contact, at the measuring tip end, a slider is provided which is displaceable in the direction of the large diameter and carries the signal conductor and the dielectric with it.

In a preferred embodiment, the earth conductor arrangement is designed in the predetermined region as a flattened tube.

Suitably, at the connecting end, a standard coaxial connector for the measuring cable is provided. The earth contact is preferably formed on the measuring tip.

By way of example, two signal conductors are provided, each with one signal contact.

The invention will now be described in greater detail with the aid of the drawings, in which:

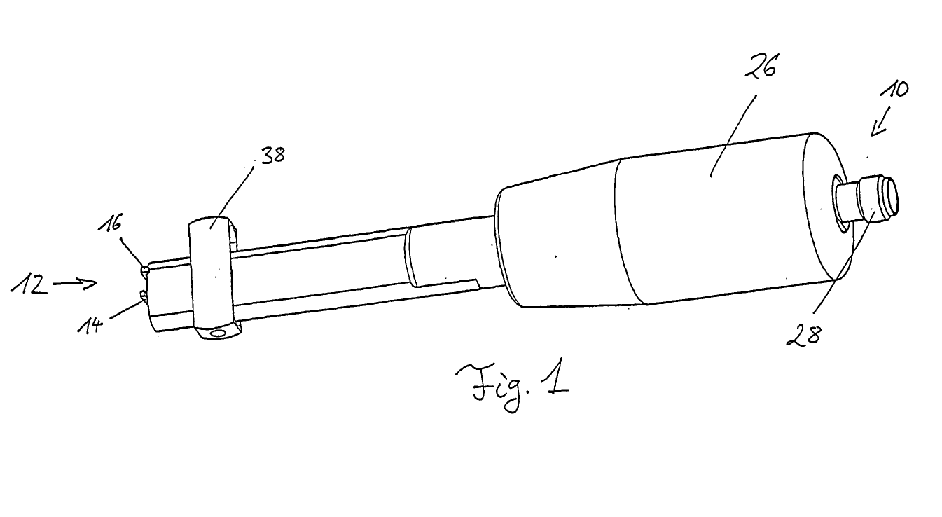

FIG. 1 shows a preferred embodiment of a high frequency probe tip according to the invention in perspective view,

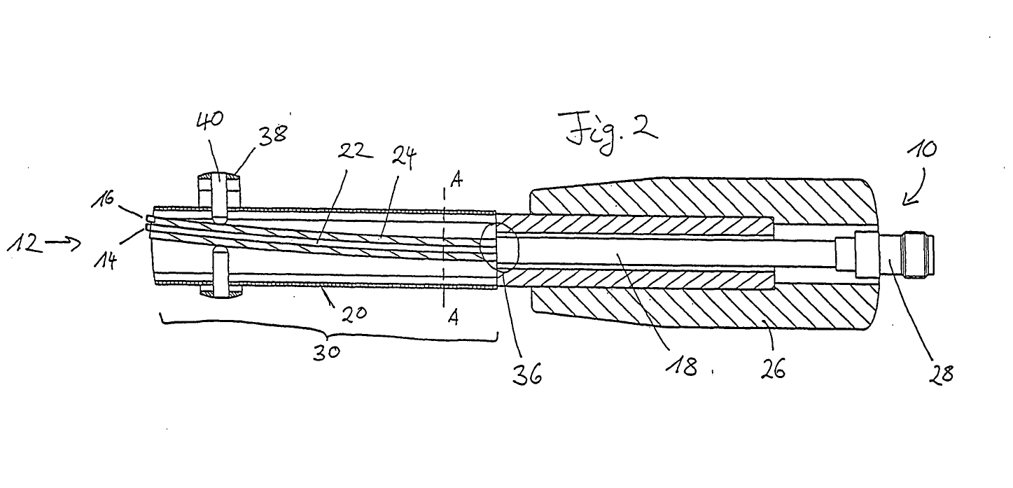

FIG. 2 shows the high frequency probe tip in FIG. 1 in longitudinal section,

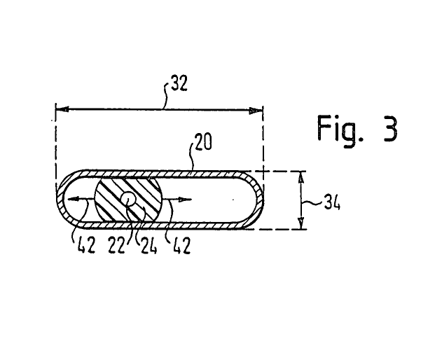

FIG. 3 shows a sectional view along the line A-A in FIG. 2,

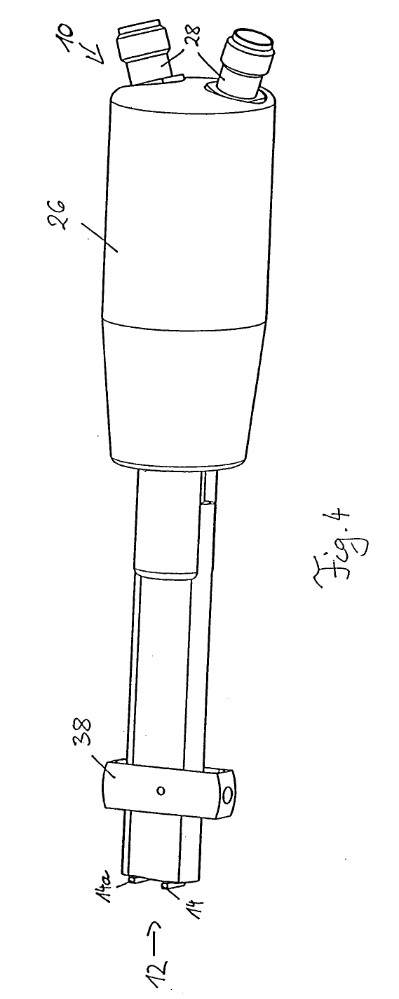

FIG. 4 shows an alternative embodiment of the high frequency probe tip according to the invention in perspective view,

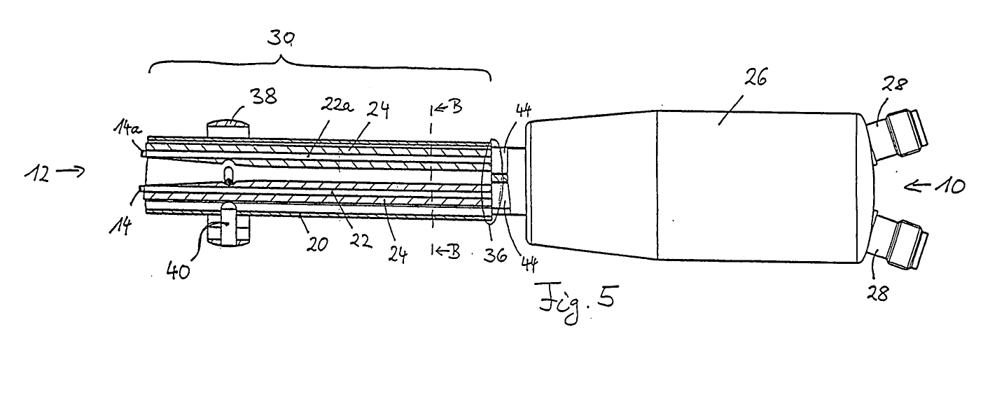

FIG. 5 shows the high frequency probe tip in FIG. 4 in longitudinal section, and

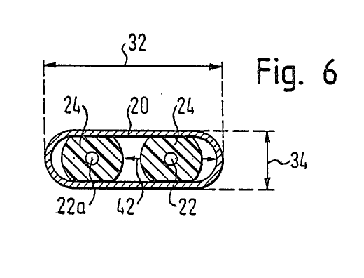

FIG. 6 shows a sectional view along the line B-B in FIG. 5.

The preferred embodiment of a high frequency probe tip according to the invention shown in FIGS. 1 and 2 includes a connecting end 10 to which a measuring cable (not shown) may be connected for linking to a measuring device (not shown), and a measuring tip 12 at which a signal contact 14 and an earth contact 16 are formed. The contacts 14, 16 form an HF transition, for instance, to a test object. A coaxial conductor 18 with an earth conductor arrangement 20 and a signal conductor 22 links the connecting end 10 to the measuring tip 12. The signal conductor 22 is surrounded by a dielectric 24. At the connecting end 10 a handle 26 is formed and a standard coaxial connector 28 for the measuring cable is arranged.

Starting from the measuring tip 12, a predetermined region 30 of the earth conductor arrangement 20 is designed as a flattened tube. As is apparent from FIG. 3, in cross-section this tube 20 has a large diameter 32 and a small diameter 34, whereby the small diameter 34 is somewhat smaller than the regular diameter of the dielectric 24. As a result, the dielectric 24 is somewhat compressed in the region 30. In the region denoted as 36, the transition from the coaxial cable 18 to the tube-shaped earth conductor arrangement 20 takes place. The sheath of the coaxial cable 18 is soldered to the open end of the tube 20, while the inner conductor or signal conductor 22 is continued as one piece with the dielectric 24. The flattening-of the tube 20 in the region 30 ensures that in this tube 20, despite the same insulator diameter, the same impedance exists as in the coaxial cable 18.

As a result of the movable signal conductor 22, a separation between the earth contact 16 and the signal contact 14 is continuously adjustable. To this end, a slider 38 (FIGS. 1, 2) is provided on the tube 20 which carries the flexible signal conductor 22 with it between pins 40. In this manner, the signal conductor 22 is slidable back and forth in the direction of the arrow 42 within the tube 20.

Despite its large adjustment range for the separation between the earth contact 16 and the signal contact 14, the measuring tip 12 has a constant impedance throughout, that is, also for all separations and is therefore suitable above all for TDR measurements whereby the measurement accuracy and resolution depend on a transition to the test object that produces as little reflection as possible. The separation of the signal contact 14 and the earth contact 16 may be altered in simple manner by actuating the slider 38. On actuation of the slider 38, the flexible inner or signal conductor 22 moves together with its insulation 24 in the box-shaped outer conductor 20. The electric field between the outer conductor 20 and the inner conductor 22 in the region 30 runs practically only through the flattened regions of the dielectric 24. The impedance is therefore independent of the position of the inner conductor 22 within the tube 20.

In the alternative embodiment shown in FIGS. 4 to 6 of a high frequency probe tip according to the invention, parts having the same function are denoted with the same reference numbers as in FIGS. 1 to 3, so that for descriptions of these, reference is made to the above description of FIGS. 1 to 3. In contrast to the embodiment according to FIGS. 1 to 3, this high frequency probe tip comprises a symmetrical tip with two signal conductors 22 and, accordingly, two signal contacts 14 on the measuring tip 12. Corresponding outer conductors of coaxial cables 44, each of which runs starting from the coaxial contacts 28 through the handle 26 are soldered at the transition region 36 onto the tube-shaped outer conductor 20. The two measuring conductors 22 designed as asymmetrical coaxial conductors (with separate earth) run together through the tube 20 and form a symmetrical conductor of doubled impedance there. Instead of the earth contact on the measuring tip 12, this high frequency probe tip therefore has a second signal contact 14a of equal value at the measuring tip 12, attached to the upper rigid conductor 22a in the drawings. The lower second conductor 22 in the drawings is displaceable in a similar manner to the asymmetrical measuring tip 12 according to FIGS. 1 to 3.

1. High frequency probe tip, particularly for printed circuit boards and/or HF cables, having a connecting end (10) to which a measuring cable may be connected for linking to a measuring device, with an earth contact (16) and a measuring tip (12), on which at least one signal contact (14) is formed, whereby a coaxial conductor (18) with an earth conductor arrangement (20) and at least one signal conductor (22) surrounded by a dielectric (24) connects the connecting end (10) to the measuring tip (12), characterised in that starting from the measuring tip (12), the earth conductor arrangement (20) is so designed over a predetermined region (30) of the high frequency probe tip that at least one of the signal conductors (22) is displaceable within the earth conductor arrangement (20) together with the dielectric (24) surrounding said signal conductor.

2. High frequency probe tip according to claim 1, characterised in that the earth conductor arrangement (20) in the predetermined region (30) is designed box-shaped.

3. High frequency probe tip according to claim 1 or 2, characterised in that the box-shaped earth conductor arrangement (20) has a small diameter and a large diameter (34, 32) in cross-section, whereby the small diameter (34) is smaller than the diameter of the dielectric (24) of the signal conductor.

4. High frequency probe tip according to claim 7, characterised in that at the measuring tip end a slider (38) is provided which is displaceable in the direction of the large diameter (32) and carries the signal conductor (22) and the dielectric (24) with it.

5. High frequency probe tip according to at least one of the previous claims, characterised in that the earth conductor arrangement (20) is designed in the predetermined region (30) as a flattened tube.

6. High frequency probe tip according to at least one of the previous claims, characterised in that at the connecting end (10), a standard coaxial connector (28) for the measuring cable is provided.

7. High frequency probe tip according to at least one of the previous claims, characterised in that two signal conductors (22) are provided each with one signal contact (14).

8. High frequency probe tip according to at least one of the previous claims, characterised in that the earth contact (16) is formed on the measuring tip (12).
